(19) United States
(12) Patent Application Publication
(10) Pub. No.: US 2007/0001212 A1
(43) Pub. Date: Jan. 4, 2007

(54) NAND-type memory devices including recessed source/drain regions and related methods

(76) Inventors: Woon-Kyung Lee, Gyeonggi-do (KR); Jeong-Hyuk Choi, Gyeonggi-do (KR)

Correspondence Address: MYERS BIGEL SIBLEY & SAJOVEC, PO BOX 37428, RALEIGH, NC, 27627, US

(21) Appl. No.: 11/431,273

(22) Filed: May 10, 2006

(30) Foreign Application Priority Data
Jun. 29, 2005 (KR) 2005-0057299

(51) Int. Cl. H01L 29/788; H01L 21/8238

(52) U.S. Cl. 257/315; 438/211; 257/317; 257/E29.3

(57) ABSTRACT

A NAND-type memory device may include first and second selection transistors on a semiconductor substrate and a plurality of memory cell transistors coupled in series between the first and second selection transistors. A first source/drain region may be shared between the first selection transistor and a first of the memory cell transistors, and a second source/drain region may be shared between the second selection transistor and a last of the memory cell transistors. Moreover, a portion of at least one of the first and/or second source/drain regions may be recessed relative to a surface of the semiconductor substrate. Related methods are also discussed.

### RELATED APPLICATION

This application claims priority from Korean Patent Application No. 10-2005-0057299, filed Jun. 29, 2005, the disclosure of which is hereby incorporated herein by reference in its entirety as if set forth fully herein.

### FIELD OF THE INVENTION

The present invention relates to electronic devices and, more particularly, to memory devices and methods of forming the same.

### BACKGROUND

A NAND-type flash memory device may provide lower operation speed than a NOR-type flash memory device. A NAND-type flash memory device, however, may provide higher integration density because a plurality of cells may share a single bit line contact. Accordingly, NAND-type flash memories may be used to store image data of a digital camera and/or micro-codes of a cellular phone.

FIG. 1 is a sectional view illustrating a conventional NAND-type non-volatile memory device. Referring to FIG. 1, an active region 2, which is defined by an isolation layer (not shown), is provided in a semiconductor substrate 1. A plurality of memory cell transistors MT1, . . . MTn may be provided on the active region 2. In addition, a string selection transistor SST and a ground selection transistor GST used to select a desired string may also be provided on the active region 2. The plurality of memory cell transistors MT1, . . . , MTn are electrically connected in series between the string selection transistor SST and the ground selection transistor GST. A drain 12 of the string selection transistor SST is connected to a bit line BL through a bit line contact plug BC, and a source 14 of the ground selection transistor GST is connected to a common source line CSL. Further, each of the memory cell transistors MT1, . . . , MTn includes a stacked gate structure disposed on a portion of the active region 2 as well as source/drain regions 16 provided in the active region 2 and self-aligned with the stacked gate structure. The stacked gate structure includes a tunnel oxide layer 4, a floating gate 6, an inter-gate dielectric layer 8 and a control gate electrode 10, which are sequentially stacked.

As NAND-type non-volatile memory devices (for example, NAND-type flash memory devices) become more highly integrated, channel lengths of the memory cell transistors and the selection transistors have been reduced. In this case, the selection transistors may exhibit a punch-through phenomenon such that some cell transistors of non-selected strings may be programmed during a program mode. In addition, as NAND-type non-volatile memory devices become more highly integrated, numbers of memory cell transistors in a single string have increased. In the event that the number of memory cell transistors in a single string increases, a cell current that flows through a selected cell transistor may be reduced in a read mode. Accordingly, a sensing margin of the highly integrated NAND-type non volatile memory device may be reduced.

A NAND-type flash memory device structure to reduce the punch-through phenomenon of the selection transistors is disclosed in U.S. Pat. No. 6,567,308 to Yim et al., entitled “NAND-Type Flash Memory Device And Method Of Forming The Same”. According to Yim et al., pockets may be formed at a drain-to-channel interface in the string selection transistor and a source-to-channel interface in the ground selection transistor to suppress and/or reduce the punch-through phenomenon of the selection transistors.

### SUMMARY

According to some embodiments of the present invention, a NAND-type memory device may include first and second selection transistors on a semiconductor substrate, and a plurality of memory cell transistors coupled in series between the first and second selection transistors. Moreover, a first source/drain region may be shared between the first selection transistor and a first of the memory cell transistors, and a second source/drain region may be shared between the second selection transistor and a last of the memory cell transistors. In addition, a portion of at least one of the first and/or second source/drain regions may be recessed relative to a surface of the semiconductor substrate.

Memory cell source/drain regions may be shared between the plurality of memory cell transistors, and an impurity concentration of at least one of the first and/or second source/drain regions may be different than an impurity concentration of at least one of the memory cell source/drain regions. Moreover, an impurity concentration of at least one memory cell source/drain regions may be greater than an impurity concentration of at least one of the first and/or second source/drain regions that is recessed relative to the surface of the semiconductor substrate.

The first source/drain region may include surface impurity regions on opposite sides of the recessed portion and a recessed impurity region coupling the surface impurity regions on opposite sides of the recessed portion. Moreover, a depth of the recessed portion may be greater than a depth of the surface impurity regions relative to the surface of the semiconductor substrate. The surface impurity regions and the recessed impurity regions may have approximately equal impurity concentrations. The first selection transistor may include a gate between a third source/drain region and the first source/drain region, and the surface impurity region of the first source/drain region and the third source/drain region may have approximately equal impurity concentrations.

Memory cell source/drain regions may be shared between the plurality of memory cell transistors, and a junction profile of at least one of the first and/or second source/drain regions may be different than a junction profile of at least one of the memory cell source/drain regions. The first selection transistor may include a gate between a third source/drain region and the first source/drain region, and the second selection transistor may include a gate between a fourth source/drain region and the second source/drain region. In addition, a bit line may be electrically connected to the third source/drain region, and a common source line may be electrically connected to the fourth source/drain region.

A depth of the recessed region may be less than a junction depth of the first source/drain region and/or the second source/drain region. For example, the recessed region may have a depth in the range of about 50 Angstroms to about 500 Angstroms.

The first selection transistor may include a first selection gate electrode on the substrate adjacent to the first source/drain region, and first and second insulating spacers on opposing sidewalls of the first selection gate electrode. Moreover, the first insulating spacer may be asymmetric with respect to the second insulating spacer. The first insulating spacer may be adjacent the first source/drain region, and the first selection gate electrode may be between the second insulating spacer and the first source/drain region with a height of the first insulating spacer being less than a height of the second insulating spacer. The first insulating spacer may be adjacent the first source/drain region, and the first selection gate electrode may be between the second insulating spacer and the first source/drain region with a height of the first insulating spacer being greater than a height of the second insulating spacer.

The first selection transistor may include a first selection gate electrode on the substrate adjacent to the first source/drain region and first and second insulating spacers on opposing sidewalls of the first selection gate electrode. The first memory cell transistor may include a first memory cell gate electrode and third and fourth insulating spacers on opposing sidewalls of the first memory cell gate electrode, and the first source/drain region may be between the first selection gate electrode and the first memory cell gate electrode. Moreover, heights of the first and second insulating spacers may be different than heights of the third and fourth insulating spacers.

The first selection transistor may include a first selection gate electrode on the substrate adjacent to the first source/drain region and selection transistor insulating spacers on opposing sidewalls of the first selection gate electrode. The plurality of memory cell transistors may include respective memory cell gate electrodes and memory cell insulating spacers on opposing sidewalls of the memory cell gate electrodes, and portions of the first source/drain region may be exposed between the selection transistor and memory cell insulating spacers. Moreover, memory cell insulating spacers of adjacent memory cell transistors may meet.

According to some other embodiments of the present invention, a NAND-type memory device may include first and second selection transistors on a semiconductor substrate, and a plurality of memory cell transistors coupled in series between the first and second selection transistors. A first source/drain region may be shared between the first selection transistor and a first of the memory cell transistors, and a second source/drain region may be shared between the second selection transistor and a last of the memory cell transistors. Memory cell source/drain regions may be shared between the plurality of memory cell transistors, and an impurity concentration of at least one of the first and/or second source/drain regions may be different than an impurity concentration of at least one of the memory cell source/drain regions.

A portion of the first source/drain region may be recessed relative to a surface of the semiconductor substrate. Moreover, the first source/drain region may include surface impurity regions on opposite sides of the recessed portion and a recessed impurity region coupling the surface impurity regions on opposite sides of the recessed portion, and a depth of the recessed portion may be greater than a depth of the surface impurity regions relative to the surface of the semiconductor substrate. The surface impurity regions and the recessed impurity regions may have approximately equal impurity concentrations. A depth of the recessed region may be less than a junction depth of the first source/drain region and/or the second source/drain region, and the recessed region may have a depth in the range of about 50 Angstroms to about 500 Angstroms.

An impurity concentration of at least one memory cell source/drain regions may be greater than an impurity concentration of at least one of the first and/or second source/drain regions. The first selection transistor may include a gate between a third source/drain region and the first source/drain region, and the first and third source/drain regions may have approximately equal impurity concentrations. A junction profile of at least one of the first and/or second source/drain regions may be different than a junction profile of at least one of the memory cell source/drain regions.

The first selection transistor may include a gate between a third source/drain region and the first source/drain region, and the second selection transistor may include a gate between a fourth source/drain region and the second source/drain region. The memory device may also include a bit line electrically connected to the third source/drain region, and a common source line electrically connected to the fourth source/drain region.

The first selection transistor may includes a first selection gate electrode on the substrate adjacent to the first source/drain region and first and second insulating spacers on opposing sidewalls of the first selection gate electrode, and the first insulating spacer may be asymmetric with respect to the second insulating spacer. The first insulating spacer may be adjacent the first source/drain region, the first selection gate electrode may be between the second insulating spacer and the first source/drain region, and a height of the first insulating spacer may be less than a height of the second insulating spacer. The first insulating spacer may be adjacent the first source/drain region, the first selection gate electrode may be between the second insulating spacer and the first source/drain region, and a height of the first insulating spacer may be greater than a height of the second insulating spacer.

The first selection transistor may include a first selection gate electrode on the substrate adjacent to the first source/drain region and first and second insulating spacers on opposing sidewalls of the first selection gate electrode. The first memory cell transistor may include a first memory cell gate electrode and third and fourth insulating spacers on opposing sidewalls of the first memory cell gate electrode. The first source/drain region may be between the first selection gate electrode and the first memory cell gate electrode, and heights of the first and second insulating spacers may be different than heights of the third and fourth insulating spacers.

The first selection transistor may include a first selection gate electrode on the substrate adjacent to the first source/drain region and selection transistor insulating spacers on opposing sidewalls of the first selection gate electrode. The plurality of memory cell transistors may include respective memory cell gate electrodes and memory cell insulating spacers on opposing sidewalls of the memory cell gate electrodes. Portions of the first source/drain region may be exposed between the selection transistor and memory cell insulating spacers, and memory cell insulating spacers of adjacent memory cell transistors may meet.

According to additional embodiments of the present invention, methods of forming a NAND-type non-volatile memory device may include forming first and second selection transistor gate electrodes on a semiconductor substrate, and forming a plurality of memory cell transistor gate electrodes coupled between the first and second selection transistor gate electrodes. First impurity ions may be implanted into portions of the semiconductor substrate between the plurality of memory cell transistor gate electrodes, between the first selection gate electrode and a first of the plurality of memory cell transistor gate electrodes, and between a last of the plurality of memory cell transistor gate electrodes and the second selection gate electrode. After implanting first impurity ions, a mask may be formed that covers portions of the semiconductor substrate between the first selection gate electrode and the first memory cell transistor gate electrode and between the last memory cell transistor gate electrode and the second selection gate electrode while exposing portions of the semiconductor substrate between at least two of the memory cell transistor gate electrodes. After forming the mask, second impurity ions may be implanted into the portions of the semiconductor substrate between at least two of the memory cell transistor gate electrodes, and after implanting second impurity ions, the mask may be removed. In addition, a recess may be formed in portions of the semiconductor substrate between the first selection gate electrode and the first memory cell transistor gate electrode.

According to still additional embodiments of the present invention, methods of forming a NAND-type non-volatile memory device may include forming first and second selection transistor gate electrodes on a semiconductor substrate, and forming a plurality of memory cell transistor gate electrodes coupled between the first and second selection transistor gate electrodes. Impurity regions may be formed in portions of the semiconductor substrate between the plurality of memory cell transistor gate electrodes, between the first selection gate electrode and a first of the plurality of memory cell transistor gate electrodes, and between a last of the plurality of memory cell transistor gate electrodes and the second selection gate electrode. In addition, a recess may be formed in portions of the semiconductor substrate between the first selection gate electrode and the first memory cell transistor gate electrode.

Forming impurity regions may include implanting first impurity ions into portions of the semiconductor substrate between the plurality of memory cell transistor gate electrodes, between the first selection gate electrode and a first of the plurality of memory cell transistor gate electrodes, and between a last of the plurality of memory cell transistor gate electrodes and the second selection gate electrode. After implanting first impurity ions, a mask may be formed that covers portions of the semiconductor substrate between the first selection gate electrode and the first memory cell transistor gate electrode and between the last memory cell transistor gate electrode and the second selection gate electrode while exposing portions of the semiconductor substrate between at least two of the memory cell transistor gate electrodes. After forming the mask, second impurity ions may be implanted into the portions of the semiconductor substrate between at least two of the memory cell transistor gate electrodes.

According to embodiments of the present invention, NAND-type non-volatile memory devices having selection transistors with reduced punchthrough characteristics may be provided. The devices may include a string selection transistor and a ground selection transistor formed at a semiconductor substrate. Each of the string selection transistor and the ground selection transistor may have selection source/drain regions spaced apart from each other. A plurality of memory cell transistors may be provided at the semiconductor substrate between the string selection transistor and the ground selection transistor. The memory cell transistors may be electrically connected in series, and each of the memory cell transistors may have cell source/drain regions spaced apart from each other. A recessed region may be provided in at least one region of the selection drain region of the ground selection transistor and the selection source region of the string selection transistor. Impurity concentrations of the selection drain region of the ground selection transistor and the selection source region of the string selection transistor may be different from an impurity concentration of at least one of the cell source/drain regions.

According to some embodiments of the present invention, an impurity concentration of the at least one region in contact with the recessed region may be lower than that of the at least one region of the cell source/drain regions.

According to other embodiments of the present invention, the at least one region in contact with the recessed region may comprise a pair of upper impurity regions formed in the substrate at both sides of the recessed region and a lower impurity region formed at inner walls of the recessed region below the upper impurity regions. The upper impurity regions may have the same impurity concentration. The at least one region in contact with the recessed region may have a different junction profile from the selection source region of the ground selection transistor or the selection drain region of the string selection transistor. The selection drain region of the string selection transistor or the selection source region of the ground selection transistor may have approximately the same impurity concentration as the upper impurity regions formed at both sides of the recessed region.

According to still other embodiments of the present invention, a bit line and a common source line may be additionally provided. The bit line may be electrically connected to the selection drain region of the string selection transistor and the common source line may be electrically connected to the selection source region of the ground selection transistor.

According to yet other embodiments of the present invention, a depth of the recessed region may be less than junction depths of the selection drain region of the ground selection transistor and the selection source region of the string selection transistor.

According to yet still other embodiments of the present invention, the recessed region may have a depth in the range of about of 50 Angstroms to about 500 Angstroms.

According to further embodiments of the present invention, each of the string selection transistor and the ground selection transistor may additionally include a selection gate structure on the substrate between the selection source/drain regions and first gate spacers on sidewalls of the selection gate structure. Each of the plurality of memory cell transistors may additionally include a cell gate structure on the substrate between the cell source/drain regions and second gate spacers on sidewalls of the cell gate structure. The first gate spacers on the both sidewalls of the ground selection gate structure or the string selection gate structure may be asymmetrical with respect to each other in shape. A height of the first gate spacer adjacent to the selection drain region of the ground selection transistor may be lower than that of the first gate spacer adjacent to the selection source region of the ground selection transistor. Also, a height of the first gate spacer adjacent to the selection source region of the string selection transistor may be lower than that of the first gate spacer adjacent to the selection drain region of the string selection transistor. Moreover, the second gate spacers may cover entire surfaces of the cell source/drain regions between the cell gate structures and may have a different height from the first gate spacers. Furthermore, each of the selection gate structures and the cell gate structures may have a gate hard mask pattern as a topmost layer thereof. The gate hard mask patterns of the selection gate structures may have partially etched upper corners, and the partially etched upper corners may be disposed adjacent to the recessed regions.

According to other embodiments of the present invention, NAND-type non-volatile memory devices may include a string selection transistor and a ground selection transistor formed at a semiconductor substrate. Each of the string selection transistor and the ground selection transistor may have selection source/drain regions spaced apart from each other. A plurality of memory cell transistors may be provided at the semiconductor substrate between the string selection transistor and the ground selection transistor. The memory cell transistors may be electrically connected in series. Each of the memory cell transistors may have cell source/drain regions spaced apart from each other, and at least one of the cell source/drain regions may include a first impurity region having a first impurity concentration and a second impurity region having a second impurity concentration region lower than the first impurity concentration. The first impurity region may be surrounded by the second impurity region.

According to some embodiments of the present invention, at least one of the cell source/drain regions may include only the first impurity region, and the cell source/drain region(s) including only the first impurity region may be disposed adjacent to the string selection transistor and/or the ground selection transistor.

According to still other embodiments of the present invention, methods of fabricating a NAND-type non-volatile memory device may be provided. The methods may include forming a first selection gate structure and a second selection gate structure on a cell region of a semiconductor substrate as well as a plurality of cell gate structures between the first and second selection gate structures. Each of the gate structures may include a tunnel oxide layer, a floating gate, an inter-gate insulating layer and a control gate electrode which are sequentially stacked. First impurity ions may be implanted into the semiconductor substrate between the gate structures to form first impurity regions. A mask layer may be formed on the substrate having the first impurity regions. The mask layer may be formed to expose at least one gap region between the plurality of cell gate structures. Second impurity ions may be implanted into the semiconductor substrate using the mask layer as an ion implantation mask, thereby forming second impurity regions. The second impurity regions may be formed to surround the first impurity regions, respectively.

According to some embodiments of the present invention, a recessed region may be additionally formed in the first impurity region between the first selection gate structure and the cell gate structure adjacent to the first selection gate structure and/or the first impurity region between the second selection gate structure and the cell gate structure adjacent to the second selection gate structure. Third impurity ions may be additionally implanted into inner walls of the recessed region.

### BRIEF DESCRIPTION OF THE DRAWINGS

FIG. 1 is a cross sectional view illustrating a conventional NAND-type non-volatile memory device.

FIG. 2 is a cross sectional view illustrating a NAND-type non-volatile memory device according to embodiments of the present invention.

FIG. 3 is an enlarged cross sectional view illustrating a portion A of FIG. 2 illustrating a NAND-type non-volatile memory device according to embodiments of the present invention.

FIG. 4 is an enlarged cross sectional view illustrating a portion A of FIG. 2 illustrating a NAND-type non-volatile memory device according to other embodiments of the present invention.

FIG. 5 is a cross sectional view illustrating a NAND-type non-volatile memory device according to still other embodiments of the present invention.

FIGS. 6A through 6D are cross sectional views illustrating methods of fabricating a NAND-type non-volatile memory device according to embodiments of the present invention.

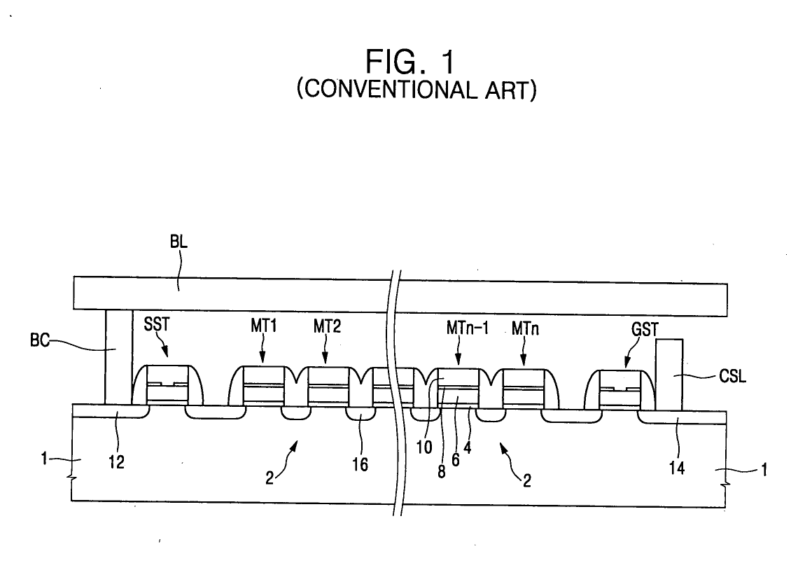

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Examples of embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

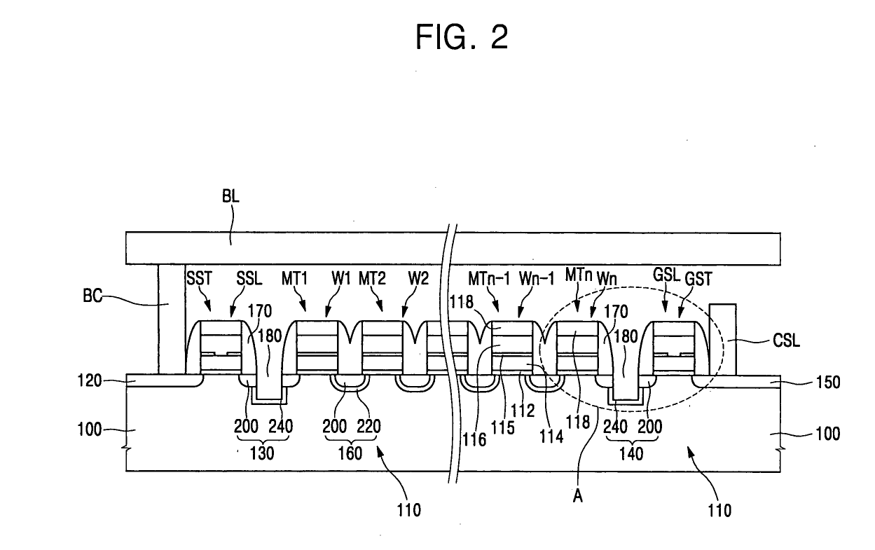

FIG. 2 is a sectional view illustrating a NAND-type non-volatile memory device according to embodiments of the present invention. Referring to FIG. 2, a trench isolation layer (not shown) may be provided in a predetermined region of a semiconductor substrate 100 to define an active region 110. N-number of cell gate structures W1 through Wn may be provided to cross over the active region 110. Each of the cell gate structures W1 through Wn may include a tunnel oxide layer 112, a floating gate electrode 114, an inter-gate insulating layer 115, a control gate electrode 116 and a hard mask pattern 118, which are sequentially stacked. The illustrated portions of the semiconductor substrate 100 may, for example, include a well doped with p-type impurities.

Cell source/drain regions 160 may be respectively provided in the active region 110 between the neighboring cell gate structures W1 through Wn. Each of the cell source/drain regions 160 may include a first impurity region 200 and a second impurity region 220 surrounding the first impurity region 200. The first and second impurity regions 200 and 220 may be impurity regions having a different conductivity type from the illustrated portions of semiconductor substrate 100. If the semiconductor substrate 100 is a p-type substrate (or a p-type well), the first and second impurity regions 200 and 220 may be n-type impurity regions. The n-type impurity regions may be impurity regions doped with phosphorus ions. Further, the first impurity region 200 may have a different impurity concentration than the second impurity region 220. For example, the first impurity region 200 may have a higher impurity concentration than the second impurity region 220.

Alternatively, each of the cell source/drain regions 160 may have only the second impurity region 220. Stated in other words, the cell source/drain regions may have a relatively uniform impurity concentration that may be relatively low. In this case, the impurity concentration of a cell source/drain region 160 including only the second impurity region 220 may be lower than that of a cell source/drain regions 160 including the first and second impurity regions 200 and 220.

A string selection line SSL (e.g., a string selection gate structure) may be provided to cross over the active region 110 adjacent to the first cell gate structure W1, and a ground selection line GSL (e.g., a ground selection gate structure) may be provided to cross over the active region 110 adjacent to the n^{th} cell gate structure Wn. Each of the selection gate structures SSL and GSL may also include a tunnel insulating layer 112, a floating gate 114, an inter-gate insulating layer 115, a control gate electrode 116 and a hard mask pattern 118, which are sequentially stacked. In this case, the floating gate 114 and the control gate electrode 116 of the selection gate structures SSL and GSL may be electrically connected through holes penetrating the inter-gate insulating layer 115 therebetween.

The first impurity region 200 may be provided in the active region 110 between the first cell gate structure W1 and the string selection gate structure SSL. Similarly, the first impurity region 200 may be provided in the active region 110 between the n^{th} cell gate structure Wn and the ground selection gate structure GSL. Furthermore, a string selection drain region 120 may be provided in the active region 110 which is adjacent to the string selection gate structure SSL and located opposite the first cell gate structure W1. A ground selection source region 150 may be provided in the active region 110 which is adjacent to the ground selection gate structure GSL and located opposite the n^{th} cell gate structure Wn. The string selection drain region 120 and the ground selection source region 150 may have a same impurity concentration and a same junction depth as the first impurity regions 200. Moreover, the string selection drain region 120, the ground selection source region 150, and the first impurity regions 200 may be formed simultaneously using a same implant operation.

Gate spacers 170 may be provided on sidewalls of the cell gate structures W1 through Wn and on sidewalls of the selection gate structures SSL and GSL. Gap regions between the cell gate structures W1 through Wn may be respectively filled with the gate spacers 170. Thus, the gate spacers 170 and/or the cell gate structures W1-Wn may completely cover surfaces of the cell source/drain regions 160. A gap region between the first cell gate structure W1 and the string selection gate structure SSL may have a greater width than gap regions between the cell gate structures W1 through Wn. Similarly, a gap region between the n^{th} cell gate structure Wn and the ground selection gate structure GSL may also have a greater width than gap regions between the cell gate structures W1 through Wn. Thus, the gate spacers 170 in the gap region between the first cell gate structure W1 and the string selection gate structure SSL as well as the gate spacers 170 in the gap region between the n^{th} cell gate structure Wn and the ground selection gate structure GSL may cover only edges of the first impurity regions 200 adjacent to the selection gate structures SSL and GSL. Accordingly, portions of the impurity regions 200 adjacent to the selection gate structures SSL and GSL may be exposed.

Recessed regions 180 may be provided to penetrate central portions of the first impurity regions 200 adjacent to the selection gate structures SSL and GSL. Alternatively, the recessed region 180 may be provided to penetrate only the first impurity region 200 adjacent to only one of the ground selection gate structure GSL or the string selection gate structure SSL. That is, the recessed region 180 may be provided to penetrate the first impurity region 200 between the n^{th} cell gate structure Wn and the ground selection gate structure GSL or to penetrate the first impurity region 200 between the first cell gate structure W1 and the string selection gate structure SSL. In this case, one of the first impurity region 200 adjacent to the string selection gate structure SSL and the first impurity region 200 adjacent to the ground selection gate structure GSL may be a planar-type impurity region without the recessed region 180.

The recessed regions 180 may be self-aligned with the gate spacers 170 and may extend into the semiconductor substrate 100. The sidewalls and the bottom surfaces of the recessed regions 180 in the semiconductor substrate 100 may be surrounded by third impurity regions 240. The third impurity regions 240 may have the same conductivity type as the first and second impurity regions 200 and 220. Further, an impurity concentration of the third impurity regions 240 may be lower than an impurity concentration of the first and second impurity regions 200 and 220. Impurities of the third impurity region 240 may be, for example, phosphorus (P) ions. The first impurity region 200 and the third impurity region 240 surrounding the recessed region 180 adjacent to the string selection gate structure SSL may provide a string selection source region 130. Also, the first impurity region 200 and the third impurity region 240 surrounding the recessed region 180 adjacent to the ground selection gate structure GSL may provide a ground selection drain region 140. A junction profile of the string selection source region 130 may be different from a junction profile of the string selection drain region 120, and a junction profile of the ground selection drain region 140 may be different from a junction profile of the ground selection source region 150.

The string selection drain region 120, the string selection gate structure SSL and the string selection source region 130 may provide a string selection transistor SST, and the ground selection drain region 140, the ground selection gate structure GSL and the ground selection source region 150 may provide a ground selection transistor GST. In addition, the first cell gate structure W1 through the n^{th} cell gate structure Wn may correspond to stacked gate structures of first to n^{th} memory cell transistors MT1 to MTn, respectively. At least one of the cell source/drain regions 160 between the first and second cell gate structures W1 and W2 and the cell source/drain region 160 between the (n−1)^{th} and n^{th} cell gate structures Wn-1 and Wn may include only the first impurity region 200. The recessed region 180 may have a depth in the range of about 50 Angstroms to about 500 Angstroms from the surface of the semiconductor substrate 100.

Each of the selection gate structures SSL and GSL may effectively have a single gate electrode. That is, each of the selection gate structures SSL and GSL may include only a tunnel insulating layer 112, a control gate electrode 116 and a hard mask pattern 118, which are sequentially stacked. Stated in other words, the floating gate 114 and the control gate electrode 116 may be electrically short-circuited in the selection gate structures SSL and GSL.

The string selection drain region 120 may be electrically connected to a bit line BL through a bit line contact plug BC, and the ground selection source region 150 may be electrically connected to a common source line CSL.

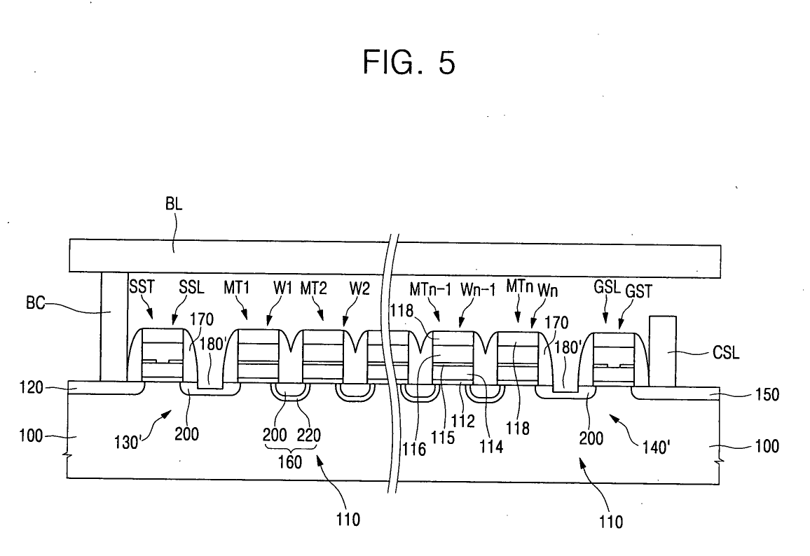

According to other embodiments of the present invention, the recessed region 180 may not penetrate completely through the first impurity region 200. In this case, a recessed region 180′ may be formed in the first impurity region 200 without completely penetrating the impurity region to provide source region 130′ and drain region 140′, and the third impurity region 240 may be omitted, as shown in FIG. 5. In other words, the depth of the recessed region 180′ may be less than the junction depth of the first impurity region 200.

As described above, the source region 130 (or 130′) of the string selection transistor SST and the drain region 140 (or 140′) of the ground selection transistor GST may provide a higher electrical resistance than a cell source/drain region 160 of at least one memory cell transistor. Further, since the recessed regions 180 (or 180′) are provided in the source region 130 (or 130′) and the drain region 140 (or 140′) a current path may be increased. As a result, a punch-through phenomenon of the selection transistors SST and/or GST may be suppressed and/or reduced and/or drain breakdown voltages of the selection transistors SST and/or GST may be increased. Thus, program disturbance characteristics may be improved. In addition, each of the cell source/drain regions 160 may include the first impurity region 200 and the second impurity region 220 to provide a relatively low electrical resistance. Accordingly, a cell current flowing through the cell source/drain regions 160 may increase. Therefore, a sensing margin may be increased in a read mode.

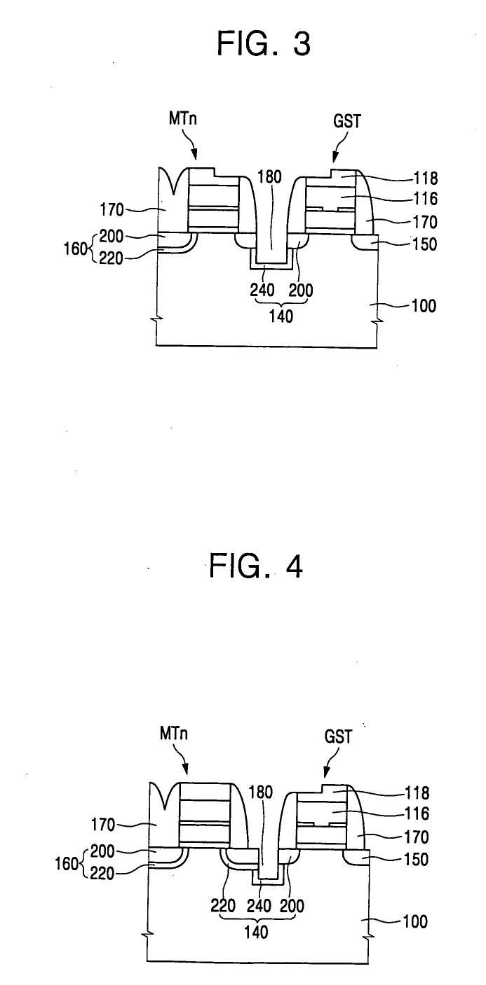

FIG. 3 is an enlarged sectional view illustrating a portion A of FIG. 2 including the ground selection transistor GST with the recessed region 180.

Referring to FIG. 3, during formation of the recessed region 180, each of the gate hard mask patterns 118 formed on the control gate electrodes 116 of the n^{th} memory cell transistor MTn and the ground selection transistor GST may be partially etched, and the gate spacers 170 on the drain region 140 of the ground selection transistor GST may also be additionally etched. As a result, a height of the gate spacers 170 on the drain region 140 may be lower than that of the gate spacer 170 on the source region 150 of the ground selection transistor GST. Therefore, the gate spacers 170 on the drain region 140 may be asymmetrical with respect to the gate spacer 170 on the source region 150. Similarly, in the event that the recessed region 180 is formed in the source region 130 of the string selection transistor SST, the height of the gate spacers 170 on the source region 130 may be lower than that of the gate spacer 170 on the drain region 120 of the string selection transistor SST. That is, the gate hard mask patterns 118 on the first memory cell transistor MT1 and the string selection transistor SST may have the same shape as the gate hard mask patterns 118 on the n^{th} memory cell transistor MTn and the ground selection transistor GST, and the gate spacers 170 on the source region 130 of the string selection transistor SST may have the same shape as the gate spacers 170 on the drain region 140 of the ground selection transistor GST. Moreover, the height of the gate spacers 170 between the cell gate structures of the memory cell transistors MT1 to MTn may be greater than that of the gate spacers 170 on the source region 130 and the drain region 140.

FIG. 4 is another enlarged sectional view of a portion A of FIG. 2 illustrating a NAND-type non-volatile memory device according to other embodiments of the present invention.

Referring to FIG. 4, during formation of the recessed region 180, the gate hard mask pattern 118 of the ground selection transistor GST may be partially etched whereas the gate hard mask pattern 118 of the n^{th} memory cell transistor MTn is not etched. Thus, only the gate spacer 170 on the sidewall of the gate structure of the ground selection transistor GST is over-etched to become lower than the gate spacer 170 on the sidewall of the gate structure of the n^{th} memory cell transistor MTn. Further, the second impurity region 220 may be additionally provided to surround the first impurity region 200 adjacent to the gate structure of the n^{th} memory cell transistor MTn. In this case, the drain region 140 may include the first impurity region 200, the third impurity region 240 formed at the bottom surface and the sidewalls of the recessed region 180, and the second impurity region 220. Similarly, in the event that the recessed region 180 is formed in the source region 130 of the string selection transistor SST, the gate hard mask pattern 118 of the string selection transistor SST may be partially etched whereas the gate hard mask pattern 118 of the first memory cell transistor MT1 is not etched. Thus, only the gate spacer 170 on the sidewall of the gate structure of the string selection transistor SST is over-etched to become lower than the gate spacer 170 on the sidewall of the gate structure of the first memory cell transistor MT1. Further, the second impurity region 220 may be additionally provided to surround the first impurity region 200 adjacent to the gate structure of the first memory cell transistor MT1. In this case, the source region 130 may also have the same shape as the drain region 140 composed of the first to third impurity regions 200, 220 and 240.

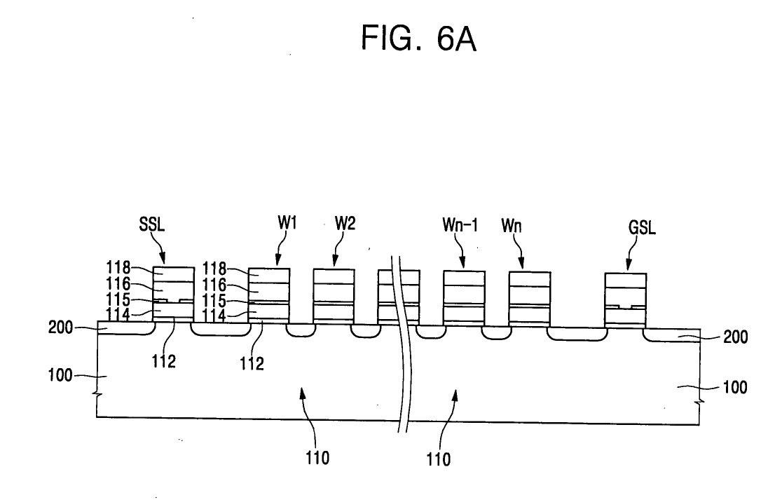

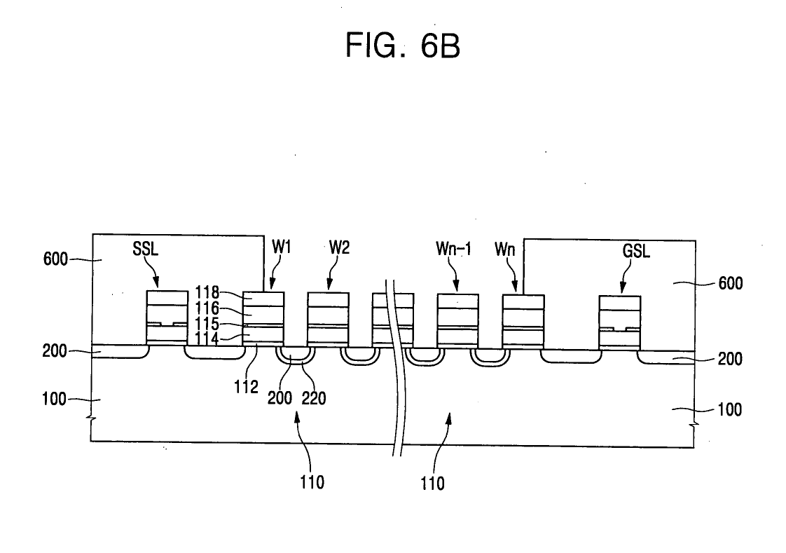

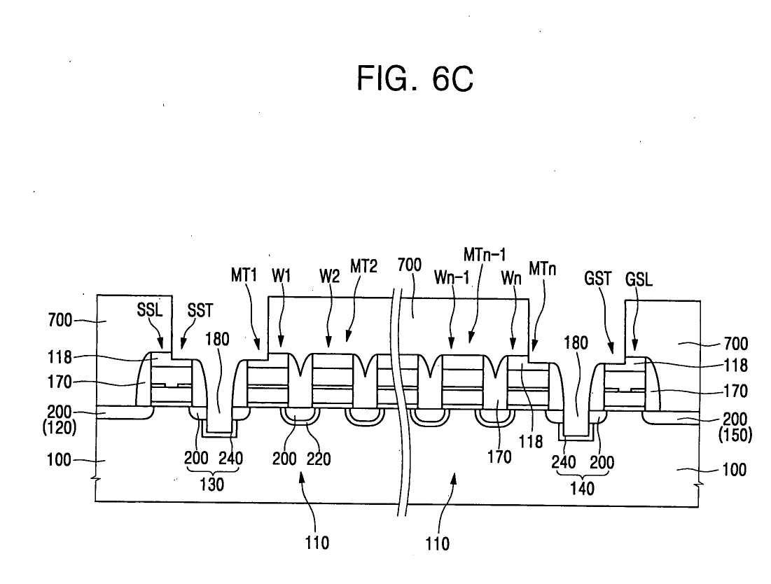

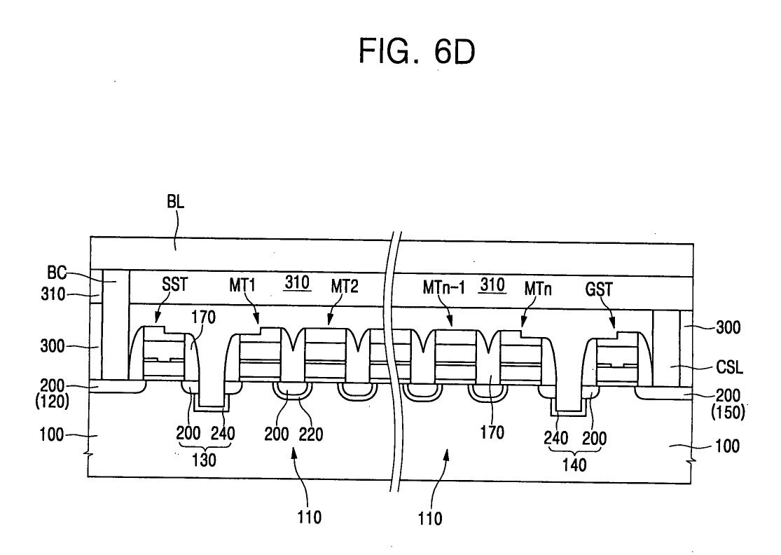

FIGS. 6A through 6D are sectional views illustrating methods of fabricating a NAND-type non-volatile memory device according to embodiments of the prevent invention.

Referring to FIG. 6A, an active region 110 may be defined at a predetermined region of a semiconductor substrate 100 using a conventional isolation technique. The active region 110 may be an active region of a memory cell region. A tunnel oxide layer 112 may be formed on the active region 110. A floating gate conductive layer (for example, a doped polysilicon layer) may be formed on the tunnel oxide layer 112. An inter-gate insulating layer and a control gate conductive layer may be sequentially formed on the substrate having the floating gate conductive layer. The inter-gate insulating layer may be formed of an oxide/nitride/oxide (ONO) layer, and the control gate conductive layer may be formed of a polycide layer including a doped polysilicon layer and a tungsten silicide layer which are sequentially formed. Further, a gate hard mask layer may be formed on the control gate conductive layer. The gate hard mask layer, the control gate conductive layer, the inter-gate insulating layer and the floating gate conductive layer may be successively patterned, thereby forming a plurality of gate structures that cross over the active region 110. While the floating gate conductive layer is patterned, the tunnel oxide layer 112 may be over-etched to expose the active region 110 between the gate structures. The gate structures may include a string selection gate structure SSL, a ground selection gate structure GSL, and n-number of cell gate structures W1 through Wn disposed between the selection gate structures SSL and GSL. As a result, each of the gate structures may be formed to include a tunnel oxide layer 112, a floating gate 114, an inter-gate insulating layer 115, a control gate electrode 116 and a hard mask pattern 118, which are sequentially stacked. The gate structures may be formed such that a distance between the string selection gate structure SSL and the first cell gate structure W1 and a distance between the ground selection gate structure GSL and the n^{th} cell gate structure Wn are greater than a distance between adjacent cell gate structures W1 through Wn.

The control gate electrodes 116 of the selection gate structures SSL and GSL may be formed to be in contact with the floating gates 114 thereof through contact holes that penetrate the inter-gate insulating layers 115. The contact holes through the inter-gate insulating layers 115 may be formed by patterning the continuous inter-gate insulating layer before forming the control gate conductive layer. First impurity ions may be implanted into the active region 110 using the gate structures SSL, W1 through Wn, and GSL as ion implantation masks, thereby forming first impurity regions 200. The first impurity ions 200 may be doped with n-type impurity ions (for example, phosphoric (P) ions). Further, the first impurity ions 200 may be implanted with energy of about 35 KeV and at a dose in the range of about 1×10¹³ to about 5×10¹³ ions/cm².

Referring to FIG. 6B, a first photoresist mask pattern 600 may be formed on the substrate including the first impurity regions 200. The first photoresist mask pattern 600 may be formed to have an opening that exposes gap regions between the cell gate structures W1 through Wn. In this case, a portion of the first cell gate structure W1 adjacent to the string selection gate structure SSL, and a portion of the n^{th} gate structure Wn adjacent to the ground selection gate structure GSL may be covered with the first photoresist mask pattern 600.

According to other embodiments of the present invention, the first photoresist mask pattern 600 may be formed to also cover at least one of the gap regions between the cell gate structures W1 through Wn. For example, if the number of the cell gate structures W1 through Wn is 32, the first photoresist mask pattern 600 may extend to cover the gap regions between the first cell gate structure W1 through the 10^{th} cell gate structure W10 as well as the gap regions between the 23^{th} cell gate structure W23 through the 32^{th} cell gate structure W32.

Second impurity ions (for example, n-type impurity ions) may be implanted into the active region 110 between the cell gate structures W1 through Wn with energy, for example, in the range of about 10 to about 50 KeV and at a dose in the range of about 1×10¹² to about 2×10¹³ ions/cm² using the first photoresist mask pattern 600 as an implantation mask. As a result, portions of second impurity regions 220 may be formed to surround the first impurity regions 200 exposed by the first photoresist mask pattern 600.

Referring to FIG. 6C, the first photoresist mask pattern 600 may be removed. An insulating layer may be formed on the substrate after removing the first photoresist mask pattern 600, and the insulating layer may be etched-back to form gate spacers 170 on sidewalls of the cell gate structures W1 through Wn and sidewalls of the selection gate structures SSL and GSL. A second photoresist mask pattern 700 may then be formed on the substrate having the gate spacers 170. The second photoresist mask pattern 700 may be formed to expose the first impurity region 200 between the string selection gate structure SSL and the first cell gate structure W1 and to expose the first impurity region 200 between the ground selection gate structure GSL and the n^{th} cell gate structure Wn. In an alternative, the second photoresist mask pattern 700 may be formed to expose only one of the first impurity region 200 between the string selection gate structure SSL and the first cell gate structure W1 or the first impurity region 200 between the ground selection gate structure GSL and the n^{th} cell gate structure Wn.

The first impurity regions 200 exposed by the second photoresist mask pattern 700 may be etched to a predetermined depth, for example, in the range of about 50 Angstroms to about 500 Angstroms, thereby forming recessed regions 180. The recessed regions 180 may penetrate the first impurity regions 200. While the recessed regions 180 are formed, the gate spacers 700 on the sidewalls of the selection gate structures SSL and GSL, the first gate structure W1, and the n^{th} gate structure Wn may act as etch masks. Thus, the recessed regions 180 may be self-aligned with respect to the gate spacers 170. Nevertheless, portions of the hard mask patterns 118 and the gate spacers 170 exposed by the second photoresist mask pattern 700 may be over-etched during formation of the recessed regions 180. As a result, the hard mask patterns 118 of the selection gate structures SSL and GSL, the first cell gate structure W1 and the n^{th} cell gate structure Wn may be partially etched as shown in FIG. 6C, and the height of the gate spacers 170 adjacent to the recessed regions 180 may be lowered and/or reduced. Using the second photoresist mask pattern 700 and the gate spacers 170 as implantation masks, third impurity ions, for example, n-type impurities such as phosphorus (P) ions, may be implanted into bottom surfaces and sidewalls of the recessed regions 180, for example, with energy in the range of about 10 to about 50 KeV and at a dose in the range of about 1×10¹¹ to about 1×10¹³ ions/cm², thereby forming third impurity regions 240 at the bottom surfaces and the sidewalls of the recessed regions 180. The first impurity region 200 and the third impurity region 240 surrounding the recessed region 180 adjacent to the string selection gate structure SSL may act as a string selection source region 130. Further, the first impurity region 200 and the third impurity region 240 surrounding the recessed region 180 adjacent to the ground selection gate structure GSL may act as a ground selection drain region 140.

The string selection gate structure SSL, the first impurity region 200, and the string selection source region 130 adjacent to the string selection gate structure SSL may provide a string selection transistor SST. The ground selection gate structure GSL, the first impurity region 200, and the ground selection drain region 140 adjacent to the ground selection gate structure GSL may provide a ground selection transistor GST. In addition, the first cell gate structure W1 through the n^{th} cell gate structure Wn may correspond to stacked gate structures of a first memory cell transistor MT1 through an n^{th} memory cell transistor MTn, respectively.

Referring to FIG. 6D, the second photoresist mask pattern 700 may be removed. A first interlayer insulating layer 300 may be formed on the substrate after the second photoresist mask pattern 700 has been removed, and a common source line CSL may be formed in the first interlayer insulating layer 300. The common source line CSL may be electrically connected to a source region 200 (or 150) of the ground selection transistor GST. A second interlayer insulating layer 310 may then be formed on the substrate having the common source line CSL, and a bit line contact plug BC may be formed in the first and second interlayer insulating layers 300 and 310. The bit line contact plug BC may be electrically connected to the drain region 120 of the string selection transistor SST. A bit line BL may be formed on the second interlayer insulating layer 310 to cover the bit line contact plug BC. While embodiments of the present invention have been discussed above with respect to NAND-type non-volatile memories having floating gate-type memory cells, other embodiments of the present invention may be applicable to other structures such as NAND-type non-volatile memory devices having charge trap-type memory cells, for example, SONOS (Semiconductor Oxide Nitride Oxide Semiconductor) memory cells.

According to embodiments of the present invention as described above, a source region of a string selection transistor and a drain region of a ground selection transistor may have impurity concentrations which are lower than that of cell source/drain regions of at least one memory cell transistor. Thus, the source region of the string selection transistor and the drain region of the ground selection transistor may have increased resistance. Further, recessed regions may be formed in the source region of the string selection transistor and the drain region of the ground selection transistor. Accordingly, a current path may be increased. A punch-through phenomenon of the selection transistors may thus be suppressed, and/or reduced and/or drain breakdown voltages of the selection transistors may be increased. As a result, a program disturbance characteristic of a NAND-type non-volatile memory device may be improved without reduction of sensing margin.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A NAND-type memory device comprising:
first and second selection transistors on a semiconductor substrate; and
a plurality of memory cell transistors coupled in series between the first and second selection transistors, wherein a first source/drain region is shared between the first selection transistor and a first of the memory cell transistors, wherein a second source/drain region is shared between the second selection transistor and a last of the memory cell transistors, and wherein a portion of at least one of the first and/or second source/drain regions is recessed relative to a surface of the semiconductor substrate.

2. A NAND-type memory device according to claim 1 wherein memory cell source/drain regions are shared between the plurality of memory cell transistors, and wherein an impurity concentration of at least one of the first and/or second source/drain regions is different than an impurity concentration of at least one of the memory cell source/drain regions.

3. A NAND-type memory device according to claim 2 wherein an impurity concentration of at least one of the memory cell source/drain regions is greater than an impurity concentration of at least one of the first and/or second source/drain regions.

4. A NAND-type memory device according to claim 1 wherein the first source/drain region comprises surface impurity regions on opposite sides of the recessed portion and a recessed impurity region coupling the surface impurity regions on opposite sides of the recessed portion, wherein a depth of the recessed portion is greater than a depth of the surface impurity regions relative to the surface of the semiconductor substrate.

5. A NAND-type memory device according to claim 4 wherein the surface impurity regions and the recessed impurity regions have approximately equal impurity concentrations.

6. A NAND-type memory device according to claim 4 wherein the first selection transistor includes a gate between a third source/drain region and the first source/drain region, wherein the surface impurity region of the first source/drain region and the third source/drain region have approximately equal impurity concentrations.

7. A NAND-type memory device according to claim 1 wherein memory cell source/drain regions are shared between the plurality of memory cell transistors, and wherein a junction profile of at least one of the first and/or second source/drain regions is different than a junction profile of at least one of the memory cell source/drain regions.

8. A NAND-type memory device according to claim 1 wherein the first selection transistor includes a gate between a third source/drain region and the first source/drain region, wherein the second selection transistor includes a gate between a fourth source/drain region and the second source/drain region, the memory device further comprising:
a bit line electrically connected to the third source/drain region; and
a common source line electrically connected to the fourth source/drain region.

9. A NAND-type memory device according to claim 1 wherein a depth of the recessed region is less than a junction depth of the first source/drain region and/or the second source/drain region.

10. A NAND-type memory device according to claim 1 wherein the recessed region has a depth in the range of about 50 Angstroms to about 500 Angstroms.

11. A NAND-type memory device according to claim 1 wherein the first selection transistor includes a first selection gate electrode on the substrate adjacent to the first source/drain region and first and second insulating spacers on opposing sidewalls of the first selection gate electrode wherein the first insulating spacer is asymmetric with respect to the second insulating spacer.

12. A NAND-type memory device according to claim 11 wherein the first insulating spacer is adjacent the first source/drain region, wherein the first selection gate electrode is between the second insulating spacer and the first source/drain region, and wherein a height of the first insulating spacer is less than a height of the second insulating spacer.

13. A NAND-type memory device according to claim 11 wherein the first insulating spacer is adjacent the first source/drain region, wherein the first selection gate electrode is between the second insulating spacer and the first source/drain region, and wherein a height of the first insulating spacer is greater than a height of the second insulating spacer.

14. A NAND-type memory device according to claim 1 wherein the first selection transistor includes a first selection gate electrode on the substrate adjacent to the first source/drain region and first and second insulating spacers on opposing sidewalls of the first selection gate electrode, wherein the first memory cell transistor includes a first memory cell gate electrode and third and fourth insulating spacers on opposing sidewalls of the first memory cell gate electrode, wherein the first source/drain region is between the first selection gate electrode and the first memory cell gate electrode, and wherein heights of the first and second insulating spacers are different than heights of the third and fourth insulating spacers.

15. A NAND-type memory device according to claim 1 wherein the first selection transistor includes a first selection gate electrode on the substrate adjacent to the first source/drain region and selection transistor insulating spacers on opposing sidewalls of the first selection gate electrode, wherein the plurality of memory cell transistors includes respective memory cell gate electrodes and memory cell insulating spacers on opposing sidewalls of the memory cell gate electrodes, wherein portions of the first source/drain region are exposed between the selection transistor and memory cell insulating spacers, and wherein memory cell insulating spacers of adjacent memory cell transistors meet.

16. A NAND-type memory device comprising:
a first selection transistor and a second selection transistor on a semiconductor substrate; and
a plurality of memory cell transistors coupled in series between the first and second selection transistors, wherein a first source/drain region is shared between the first selection transistor and a first of the memory cell transistors, wherein a second source/drain region is shared between the second selection transistor and a last of the memory cell transistors, wherein memory cell source/drain regions are shared between the plurality of memory cell transistors, and wherein an impurity concentration of at least one of the first and/or second source/drain regions is different than an impurity concentration of at least one of the memory cell source/drain regions.

17. A NAND-type memory device according to claim 16 wherein an impurity concentration of at least one of the memory cell source/drain regions is greater than an impurity concentration of at least one of the first and/or second source/drain regions.

18. A NAND-type memory device according to claim 16 wherein a portion of the first source/drain region is recessed relative to a surface of the semiconductor substrate.

19. A NAND-type memory device according to claim 18 wherein the first source/drain region comprises surface impurity regions on opposite sides of the recessed portion and a recessed impurity region coupling the surface impurity regions on opposite sides of the recessed portion, wherein a depth of the recessed portion is greater than a depth of the surface impurity regions relative to the surface of the semiconductor substrate.

20. A NAND-type memory device according to claim 19 wherein the surface impurity regions and the recessed impurity regions have approximately equal impurity concentrations.

21. A NAND-type memory device according to claim 18 wherein a depth of the recessed region is less than a junction depth of the first source/drain region and/or the second source/drain region.

22. A NAND-type memory device according to claim 18 wherein the recessed region has a depth in the range of about 50 Angstroms to about 500 Angstroms.

23. A NAND-type memory device according to claim 16 wherein the first selection transistor includes a gate between a third source/drain region and the first source/drain region, wherein the first and third source/drain regions have approximately equal impurity concentrations.

24. A NAND-type memory device according to claim 16 wherein a junction profile of at least one of the first and/or second source/drain regions is different than a junction profile of at least one of the memory cell source/drain regions.

25. A NAND-type memory device according to claim 16 wherein the first selection transistor includes a gate between a third source/drain region and the first source/drain region, wherein the second selection transistor includes a gate between a fourth source/drain region and the second source/drain region, the memory device further comprising:
a bit line electrically connected to the third source/drain region; and
a common source line electrically connected to the fourth source/drain region.

26. A NAND-type memory device according to claim 16 wherein the first selection transistor includes a first selection gate electrode on the substrate adjacent to the first source/drain region and first and second insulating spacers on opposing sidewalls of the first selection gate electrode wherein the first insulating spacer is asymmetric with respect to the second insulating spacer.

27. A NAND-type memory device according to claim 26 wherein the first insulating spacer is adjacent the first source/drain region, wherein the first selection gate electrode is between the second insulating spacer and the first source/drain region, and wherein a height of the first insulating spacer is less than a height of the second insulating spacer.

28. A NAND-type memory device according to claim 26 wherein the first insulating spacer is adjacent the first source/drain region, wherein the first selection gate electrode is between the second insulating spacer and the first source/drain region, and wherein a height of the first insulating spacer is greater than a height of the second insulating spacer.

29. A NAND-type memory device according to claim 16 wherein the first selection transistor includes a first selection gate electrode on the substrate adjacent to the first source/drain region and first and second insulating spacers on opposing sidewalls of the first selection gate electrode, wherein the first memory cell transistor includes a first memory cell gate electrode and third and fourth insulating spacers on opposing sidewalls of the first memory cell gate electrode, wherein the first source/drain region is between the first selection gate electrode and the first memory cell gate electrode, and wherein heights of the first and second insulating spacers are different than heights of the third and fourth insulating spacers.

30. A NAND-type memory device according to claim 16 wherein the first selection transistor includes a first selection gate electrode on the substrate adjacent to the first source/drain region and selection transistor insulating spacers on opposing sidewalls of the first selection gate electrode, wherein the plurality of memory cell transistors includes respective memory cell gate electrodes and memory cell insulating spacers on opposing sidewalls of the memory cell gate electrodes, wherein portions of the first source/drain region are exposed between the selection transistor and memory cell insulating spacers, and wherein memory cell insulating spacers of adjacent memory cell transistors meet.

31. A method of forming a NAND-type non-volatile memory device, the method comprising:
forming first and second selection transistor gate electrodes on a semiconductor substrate;
forming a plurality of memory cell transistor gate electrodes between the first and second selection transistor gate electrodes;
implanting first impurity ions into portions of the semiconductor substrate between the plurality of memory cell transistor gate electrodes, between the first selection gate electrode and a first of the plurality of memory cell transistor gate electrodes, and between a last of the plurality of memory cell transistor gate electrodes and the second selection gate electrode;
after implanting first impurity ions, forming a mask that covers portions of the semiconductor substrate between the first selection gate electrode and the first memory cell transistor gate electrode and between the last memory cell transistor gate electrode and the second selection gate electrode while exposing portions of the semiconductor substrate between at least two of the memory cell transistor gate electrodes; and
after forming the mask, implanting second impurity ions into the portions of the semiconductor substrate between at least two of the memory cell transistor gate electrodes.

32. A method according to claim 31 further comprising:
forming a recess in portions of the semiconductor substrate between the first selection gate electrode and the first memory cell transistor gate electrode.

33. A method of forming a NAND-type non-volatile memory device, the method comprising:
forming first and second selection transistor gate electrodes on a semiconductor substrate;
forming a plurality of memory cell transistor gate electrodes coupled between the first and second selection transistor gate electrodes;
forming impurity regions in portions of the semiconductor substrate between the plurality of memory cell transistor gate electrodes, between the first selection gate electrode and a first of the plurality of memory cell transistor gate electrodes, and between a last of the plurality of memory cell transistor gate electrodes and the second selection gate electrode; and
forming a recess in portions of the semiconductor substrate between the first selection gate electrode and the first memory cell transistor gate electrode.

34. A method according to claim 33 wherein forming impurity regions further comprises:
implanting first impurity ions into portions of the semiconductor substrate between the plurality of memory cell transistor gate electrodes, between the first selection gate electrode and a first of the plurality of memory cell transistor gate electrodes, and between a last of the plurality of memory cell transistor gate electrodes and the second selection gate electrode;
after implanting first impurity ions, forming a mask that covers portions of the semiconductor substrate between the first selection gate electrode and the first memory cell transistor gate electrode and between the last memory cell transistor gate electrode and the second selection gate electrode while exposing portions of the semiconductor substrate between at least two of the memory cell transistor gate electrodes; and
after forming the mask, implanting second impurity ions into the portions of the semiconductor substrate between at least two of the memory cell transistor gate electrodes.
